(19) United States
(12) Patent Application Publication
(10) Pub. No.: US 2025/0227974 A1
(43) Pub. Date: Jul. 10, 2025

(54) NITRIDE SEMICONDUCTOR DEVICE AND METHOD FOR MANUFACTURING THE SAME

(71) Applicant: ELECTRONICS AND TELECOMMUNICATIONS RESEARCH INSTITUTE, Daejeon (KR)

(72) Inventor: Hyung Seok LEE, Daejeon (KR)

(73) Assignee: ELECTRONICS AND TELECOMMUNICATIONS RESEARCH INSTITUTE, Daejeon (KR)

(21) Appl. No.: 18/920,031

(22) Filed: Oct. 18, 2024

(30) Foreign Application Priority Data
Jan. 10, 2024 (KR) 10-2024-0004194
May 27, 2024 (KR) 10-2024-0068633

(51) Int. Cl. H01L 29/20; H01L 21/02; H01L 29/06

(52) U.S. Cl. CPC H10D 62/8503; H01L 21/02389; H01L 21/0254; H10D 62/102

(57) ABSTRACT

Provided is a nitride semiconductor device including a nitride substrate of a first conductive type including an device region and a peripheral region, a first nitride layer of the first conductive type disposed on the nitride substrate, a second nitride layer of a second conductive type disposed on the first nitride layer in the device region, guard rings disposed on the first nitride layer in the peripheral region, and an impurity region of the second conductive type adjacent to each of the guard rings in the second nitride layer, wherein an upper surface of the first nitride layer is located at a higher level in the device region than in the peripheral region.

### CROSS-REFERENCE TO RELATED APPLICATIONS

This U.S. non-provisional patent application claims priority under 35 U.S.C. § 119 of Korean Patent Application No. 10-2024-0004194, filed on Jan. 10, 2024, and 10-2024-0068633 filed on May 27, 2024, the entire contents of which are hereby incorporated by reference.

### BACKGROUND

The present disclosure herein relates to a semiconductor device, and more particularly, to a vertical nitride semiconductor device.

Breakdown voltage is one of the critical factors in power semiconductor devices. Because junctions of the semiconductor devices are finite, electric fields concentrate at an edge of an active region, and this field concentration initiates avalanche breakdown, determining the breakdown voltage of the semiconductor devices. The breakdown voltage of the semiconductor devices may be improved by forming a junction termination region at the edge of the active region to mitigate the electric field concentration.

A PIN diode is constructed with an undoped intrinsic semiconductor sandwiched between a p-type semiconductor region and an n type semiconductor region. Under forward bias, carriers are injected into an intrinsic semiconductor layer, and subsequent carrier recombination leads to forward current. Under reverse bias, a space charge region widens, resulting in a small leakage current. However, carriers exceeding reverse potential gain high energy and collide with atoms in the space charge region, causing exponentially increasing carriers and resulting in a rapid increase in reverse current, leading to avalanche breakdown.

Nitride semiconductors, in particular, are wide bandgap semiconductors, having higher electric field strength and higher electron mobility than silicon, and thus are attracting much attention as next-generation power semiconductor materials. While typical nitride semiconductors have been fabricated through heteroepitaxial growth of GaN on substrates such as Si, SiC, or Al₂O₃, recent developments in nitride substrates have enabled homoepitaxial growth of GaN on nitride semiconductor substrates, leading to the development of nitride semiconductor devices based on this approach.

To increase the breakdown voltage of vertical nitride semiconductor devices, it is essential to optimize junction termination for reducing electric fields in the vicinity of the etched termination and junction edge of the P-N junction, but there are several technical challenges. First, an ion-implantation based edge termination technique based on p-type Mg ion-implantation is used to optimize techniques for junction edge and junction termination, but high ion-implantation energy may introduce significant defects into nitride materials. Second, activation of implanted ions in typical nitride semiconductors generally requires a heat treatment at a temperature of 1300° C. or greater, but the activation at high temperatures may damage nitride surfaces. Third, etching may lead to defects in areas other than the intended target during the etching process and the complexity of the process may contribute to increased process costs.

### SUMMARY

The present disclosure provides a nitride semiconductor device having high breakdown voltage, using a self-edge termination structure.

The present disclosure also provides a nitride semiconductor device having enhanced leakage current characteristics resulting from the reduction in surface damage caused by high energy.

The present disclosure is not limited to the technical problems described above, and those skilled in the art may understand other technical problems from the following description.

An embodiment of the inventive concept provides a nitride semiconductor device including a nitride substrate of a first conductive type including an device region and a peripheral region, a first nitride layer of the first conductive type disposed on the nitride substrate, a second nitride layer of a second conductive type disposed on the first nitride layer in the device region, guard rings disposed on the first nitride layer in the peripheral region, and an impurity region of the second conductive type adjacent to each of the guard rings in the second nitride layer, wherein an upper surface of the first nitride layer is located at a higher level in the device region than in the peripheral region.

In an embodiment of the inventive concept, a nitride semiconductor device includes a nitride substrate of a first conductive type including an device region, a peripheral region, and a boundary region placed between the device region and the peripheral region, a first nitride layer of the first conductive type on the nitride substrate, wherein an upper surface of the first nitride layer is located at a higher level in the device region than in the peripheral region, a second nitride layer of a second conductive type disposed on the first nitride layer of the device region and the boundary region, guard rings disposed on the first nitride layer of the peripheral region, and an impurity region of the second conductive type adjacent to each of the guard rings in the first nitride layer of the peripheral region, wherein the first nitride layer has a first inclined plane in the boundary region, the second nitride layer has a second inclined plane in the boundary region, and the first inclined plane and the second inclined plane have an inclination angle of about 5° to less than about 900 with respect to an upper surface of the nitride substrate.

In an embodiment of the inventive concept, a method for manufacturing a nitride semiconductor device includes sequentially stacking a first nitride layer of a first conductive type and a second nitride layer of a second conductive type on a nitride substrate of the first conductive type including an device region and a peripheral region to form a semiconductor stack, sequentially etching the second nitride layer in the peripheral region and a portion of the first nitride layer in the peripheral region to expose an upper surface of the first nitride layer in the peripheral region, performing a deposition process to form guard rings on the first nitride layer in the peripheral region, and performing a heat treatment process to form an impurity region of the second conductive type adjacent to each of the guard rings in the first nitride layer of the peripheral region.

Specific details of other embodiments are included in the detailed description and drawings.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a cross-sectional view showing a nitride semiconductor device according to an embodiment of the inventive concept;

FIGS. 2 and 3 are cross-sectional views showing a nitride semiconductor device according to another embodiment of the inventive concept;

FIGS. 4 to 6 are views showing experimental data for an embodiment of FIG. 1;

FIG. 7 is a cross-sectional view showing a nitride semiconductor device according to Comparative Example corresponding to the inventive concept;

FIGS. 8 to 10 are views showing experimental data for Comparative Example of FIG. 7;

FIG. 11 is a flowchart for schematically describing a method for manufacturing a nitride semiconductor device according to an embodiment of the inventive concept;

FIG. 12 is a cross-sectional view for describing a method for manufacturing a nitride semiconductor device according to an embodiment of the inventive concept;

FIG. 13 is a cross-sectional view for describing a method for manufacturing a nitride semiconductor device according to another embodiment of the inventive concept; and

FIGS. 14 and 15 are cross-sectional views for describing a method for manufacturing a nitride semiconductor device according to embodiments of the inventive concept.

### DETAILED DESCRIPTION

Hereinafter, a nitride semiconductor device and a method for manufacturing the same according to embodiments of the inventive concept will be described with reference to the accompanying drawings.

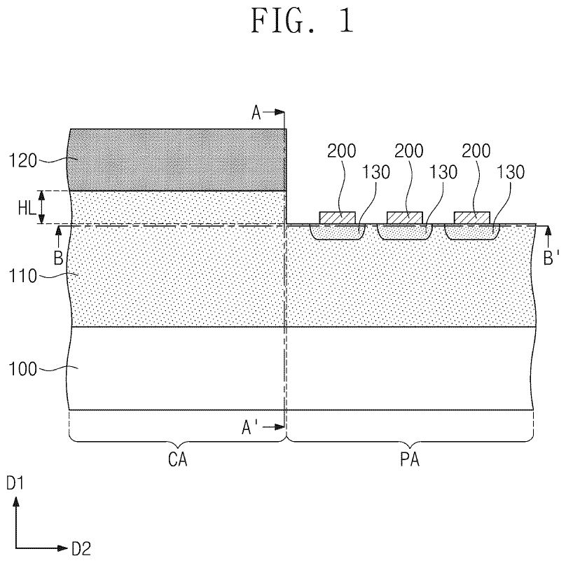

FIG. 1 is a cross-sectional view showing a nitride semiconductor device according to an embodiment of the inventive concept.

Referring to FIG. 1, the nitride semiconductor device according to an embodiment of the inventive concept may include an device region CA and a peripheral region PA. The nitride semiconductor device may include a nitride substrate 100, a first nitride layer 110, a second nitride layer 120, an impurity region 130, and guard rings 200.

The nitride substrate 100 may include impurities of a first conductive type. For example, the nitride substrate 100 may be of n+ type, and the first conductive type may be of n type. The nitride substrate 100 may include a nitride semiconductor (e.g., GaN).

The first nitride layer 110 may be provided on the nitride substrate 100. The first nitride layer 110 may include impurities of the first conductive type. For example, the first nitride layer 110 may be of n type. For example, the first nitride layer 110 has an impurity concentration of about 10¹⁵ to about 5*10¹⁶ per cubic centimeter. The first nitride layer 110 may include a nitride semiconductor (e.g., GaN).

An upper surface of the first nitride layer 110 in the device region CA may be placed at a higher level than an upper surface of the first nitride layer 110 in the peripheral region PA. A thickness of the first nitride layer 110 in the device region CA may be greater than a thickness of the first nitride layer 110 in the peripheral region PA. A level difference HL may be defined as a height difference between the upper surface of the first nitride layer 110 in the device region CA and the upper surface of the first nitride layer 110 in the peripheral region PA in a first direction D1 perpendicular to an upper surface of the nitride substrate 100. The level difference HL may be about 100 nm to about 300 nm. A second direction D2 may be a direction perpendicular to the first direction D1 and parallel to the nitride substrate 100.

The second nitride layer 120 may be provided on the first nitride layer 110 in the device region CA. The second nitride layer 120 may include impurities of a second conductive type. For example, the second nitride layer 120 may be of p+ type, and the second conductive type may be of p type. The second nitride layer 120 may include a nitride semiconductor (e.g., GaN).

A thickness of the second nitride layer 120 may be greater than the level difference HL.

The guard rings 200 may be provided on the first nitride layer 110 in the peripheral region PA. The guard rings 200 may be provided in plurality. The guard rings 200 may each be disposed to be spaced apart from each other. Although not shown, the guard rings 200 may have a ring shape surrounding the device region CA. The guard rings 200 may include a metal material. The metal material may be an impurity material of the second conductive type (e.g., Mg).

An upper surface of the guard rings 200 may be placed at a lower level than a lower surface of the second nitride layer 120. That is, a thickness of the guard rings 200 in the first direction D1 may be smaller than the level difference HL.

The impurity region 130 may be provided within the first nitride layer 110 in the peripheral region PA. The impurity region 130 may be provided adjacent to the guard rings 200. That is, the impurity region 130 may be a region in which the first nitride layer 110 and the guard rings 200 come into contact.

The impurity region 130 may include impurities of the second conductive type. For example, the impurity region 130 may include p-type impurities (e.g., Mg). For example, the impurity region 130 has an impurity concentration of about 10¹⁶ to about 10¹⁸ per cubic centimeter. The impurity region 130 may include a nitride semiconductor (e.g., GaN). A depth of the impurity region 130 in the first direction D1 may be about 10 nm to about 200 nm.

The nitride semiconductor device according to embodiments of the inventive concept may have a self-edge termination structure. In a vertical nitride semiconductor device, the self-edge termination structure may be a structure in which the guard rings 200 are provided on the first nitride layer 110 in the peripheral region PA, and the impurity region 130 is provided in an area adjacent to the guard rings 200 in the peripheral region PA.

The nitride semiconductor device according to an embodiment of the inventive concept may prevent electric fields from being concentrated in the device region CA through the self-edge termination structure. Accordingly, avalanche breakdown may be prevented at an end of the device region CA, and the nitride semiconductor device may have enhanced breakdown voltage.

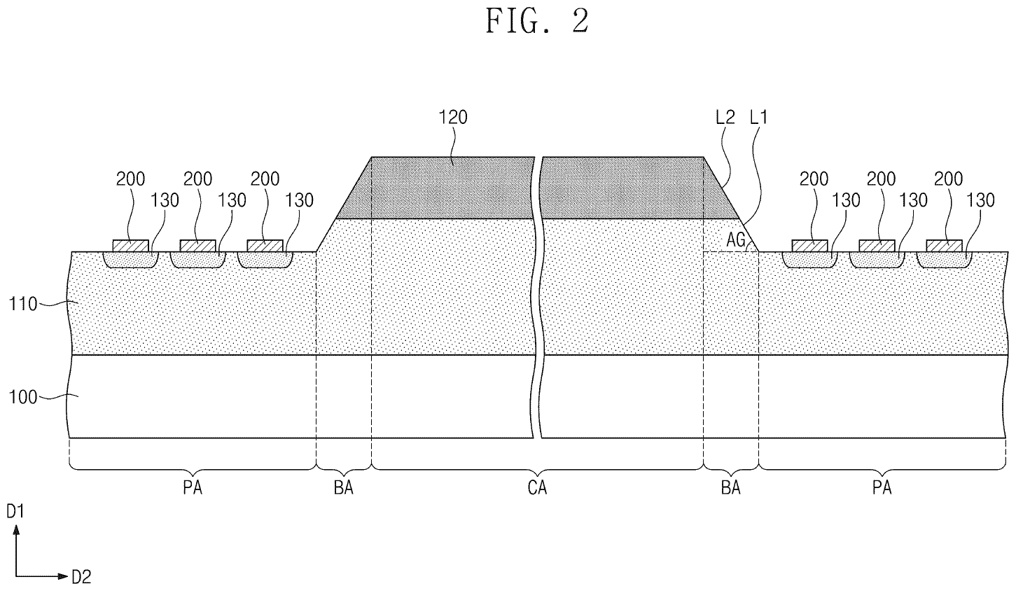

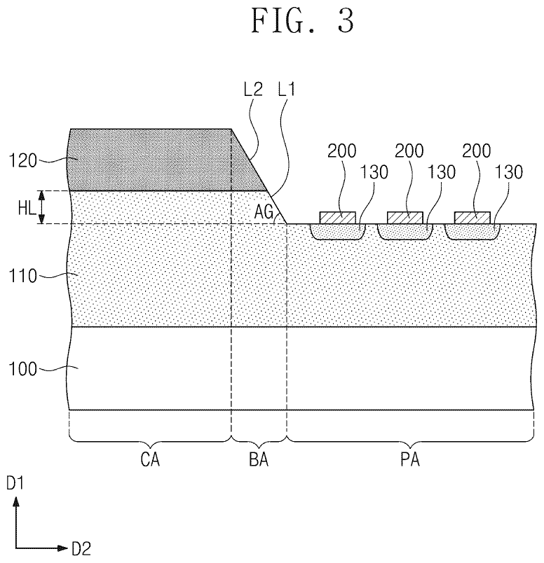

FIGS. 2 and 3 are cross-sectional views showing a nitride semiconductor device according to another embodiment of the inventive concept. Yet, differences from the nitride semiconductor device according to an embodiment of the inventive concept described above will be mainly described. For brevity, detailed descriptions of components that are identical/similar to those described above may be skipped.

Referring to FIGS. 2 and 3, the nitride semiconductor device according to another embodiment of the inventive concept may include an device region CA, a peripheral region PA, and a boundary region BA placed between the device region CA and the peripheral region PA.

A first nitride layer 110 may include a first inclined plane L1 in the boundary region BA. The first inclined plane L1 may have an inclination angle AG with respect to an upper surface of the first nitride layer 110 in the peripheral region PA. The inclination angle AG may be about 5° to about 90°.

A second nitride layer 120 may be provided on the first nitride layer 110 in the device region CA and the boundary region BA.

The second nitride layer 120 may include a second inclined plane L2 in the boundary region BA. The second inclined plane L2 may have an inclination angle AG with respect to the upper surface of the first nitride layer 110 in the device region CA, and thus may have substantially the same inclination as the first inclined plane L1.

Although not shown, guard rings 200 may have a ring shape surrounding the device region CA and the boundary region BA.

The nitride semiconductor device according to an embodiment of the inventive concept may have a MESA structure. The self-edge termination structure and the first and second inclined planes L1 and L2 on the boundary region BA may prevent electric fields from being concentrated in the device region CA. Accordingly, avalanche breakdown may be prevented at an end of the device region CA, and the nitride semiconductor device may have enhanced breakdown voltage.

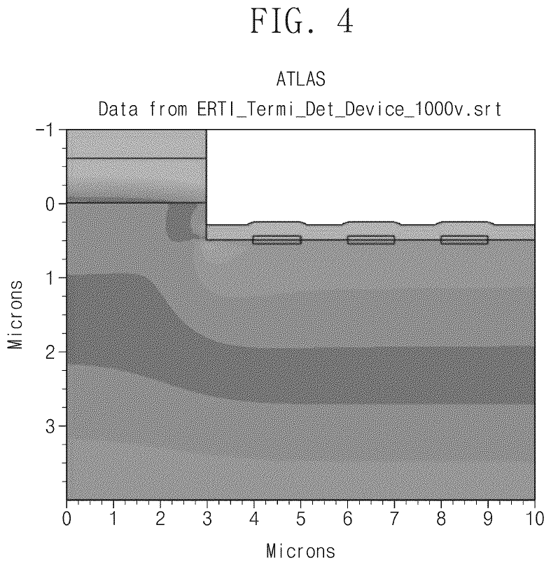

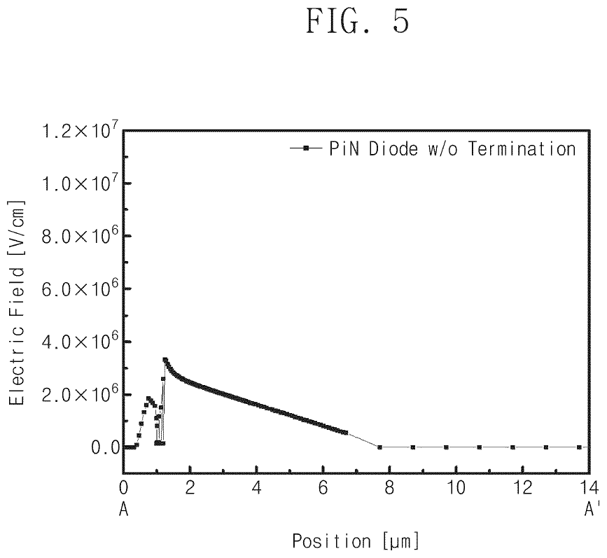

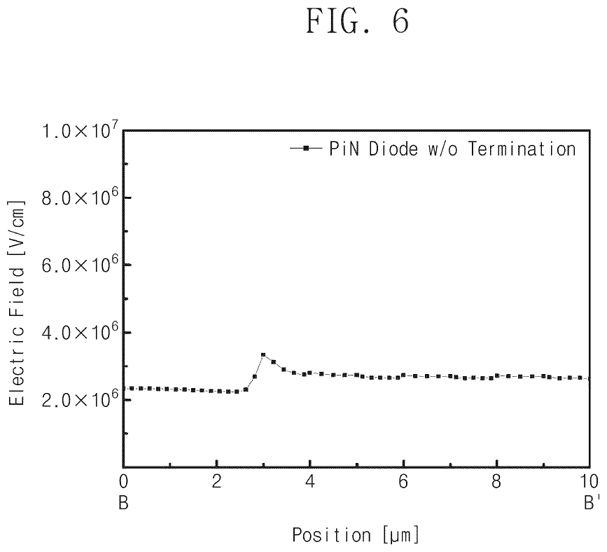

FIGS. 4 to 6 are views showing experimental data for an embodiment of FIG. 1. FIG. 4 is a two-dimensional graph schematically showing electric field values for an embodiment of FIG. 1. FIG. 5 is a graph schematically showing electric field values for line A-A′ of FIG. 1 according to location. FIG. 6 is a graph schematically showing electric field values for line B-B′ of FIG. 1 according to location.

Referring to FIGS. 4 to 6, the nitride semiconductor device corresponding to an embodiment of FIG. 1 may have a largest electric field value at the junction of lines A-A′ and line B-B′ in FIG. 1. A peak electric field value may be about 3.5*10⁶ V/cm.

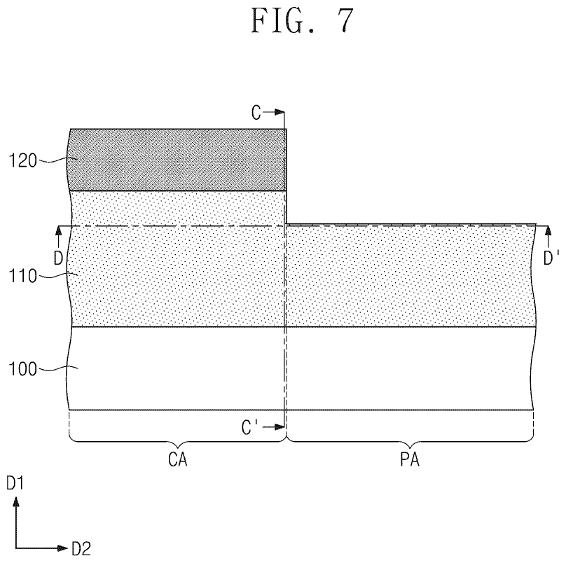

FIG. 7 is a cross-sectional view showing a nitride semiconductor device according to Comparative Example corresponding to the inventive concept. Yet, differences from the nitride semiconductor device according to an embodiment of the inventive concept described above will be mainly described. For brevity, detailed descriptions of components that are identical/similar to those described above may be skipped.

Referring to FIG. 7, unlike the embodiments described above, the guard rings 200 on the peripheral region PA may be skipped, and an impurity region 130 in the first nitride layer 110 may be skipped. That is, Comparative Example may be a vertical nitride semiconductor device in which the self-edge termination structure is not provided.

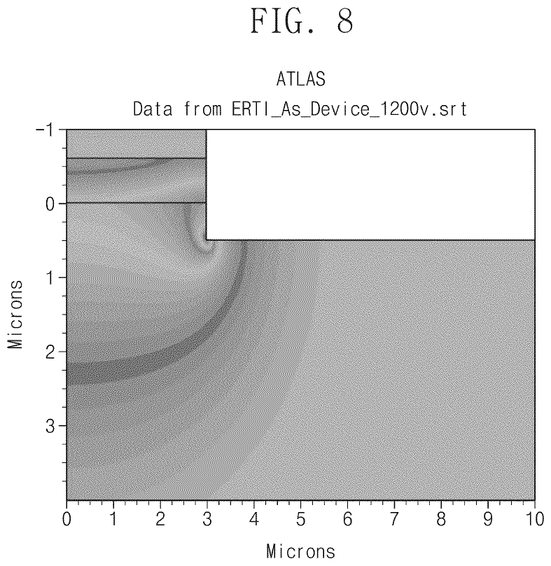

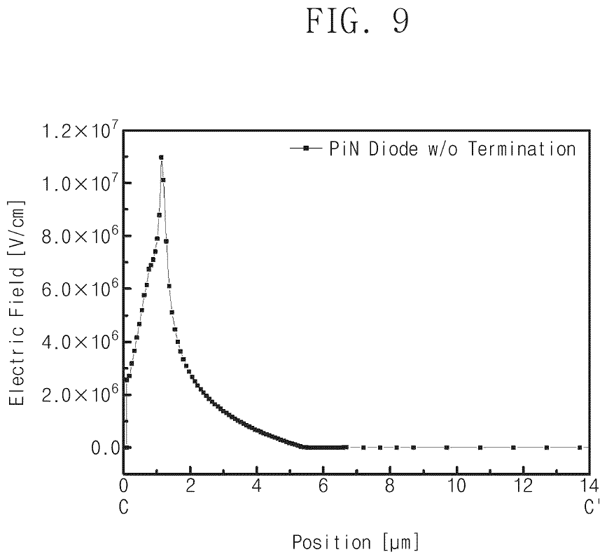

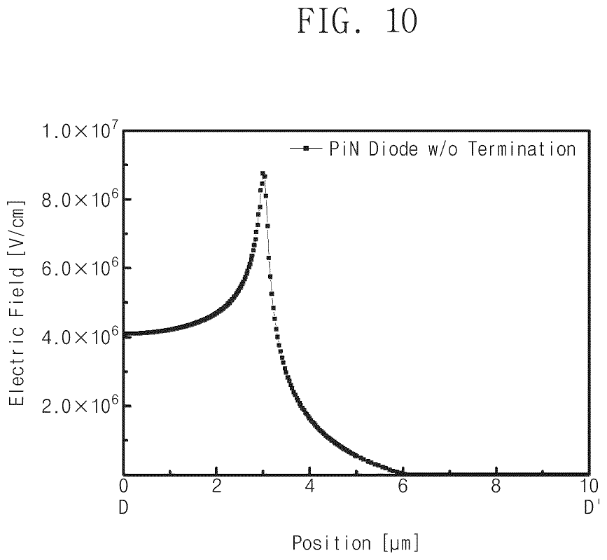

FIGS. 8 to 10 are views showing experimental data for an Comparative Example of FIG. 7. FIG. 8 is a two-dimensional graph schematically showing electric field values for an embodiment of FIG. 7. FIG. 9 is a graph schematically showing electric field values for line C-C′ of FIG. 7 according to location. FIG. 10 is a graph schematically showing electric field values for line D-D′ of FIG. 7 according to location.

Referring to FIGS. 8 to 10, the nitride semiconductor device corresponding to Comparative Example of FIG. 7 may have a largest electric field value at the junction of lines C-C′ and line D-D′ in FIG. 7. A peak electric field value may be about 1.1*10⁷ V/cm.

Compared to experimental data of FIGS. 4 to 6, the nitride semiconductor device according to an embodiment of the inventive concept may have a peak electric field value reduced by about 68% compared to Comparative Example in which the self-edge termination structure is not provided. That is, the nitride semiconductor device having a self-edge termination structure according to an embodiment of the inventive concept may suppress a peak electric field value at an edge junction between the first nitride layer 110 and the second nitride layers 120. Accordingly, the nitride semiconductor device may have enhanced breakdown voltage.

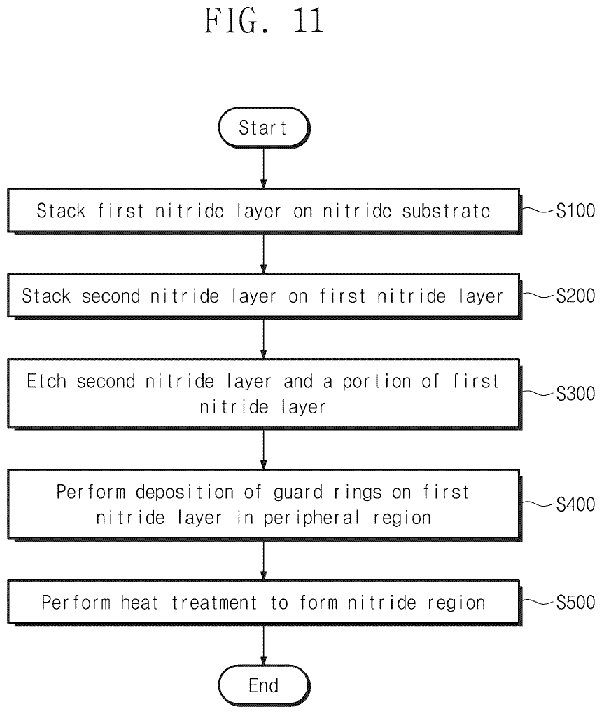

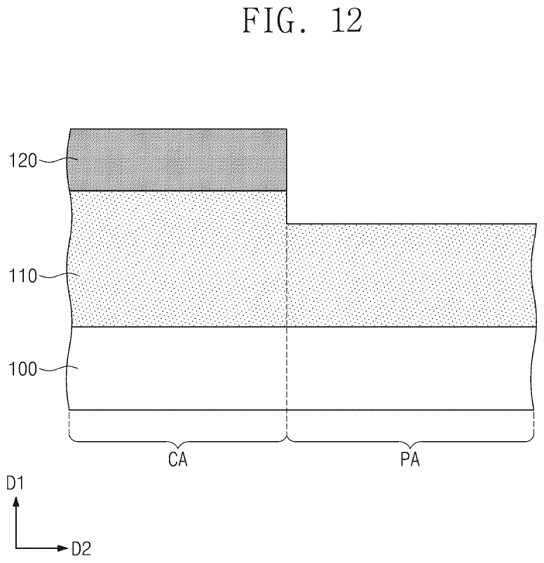

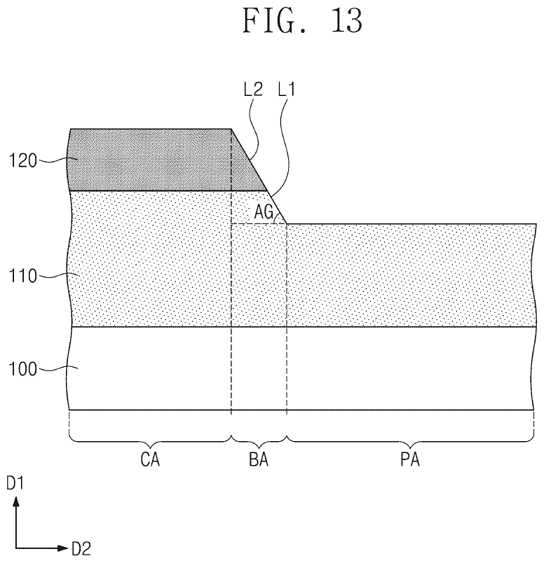

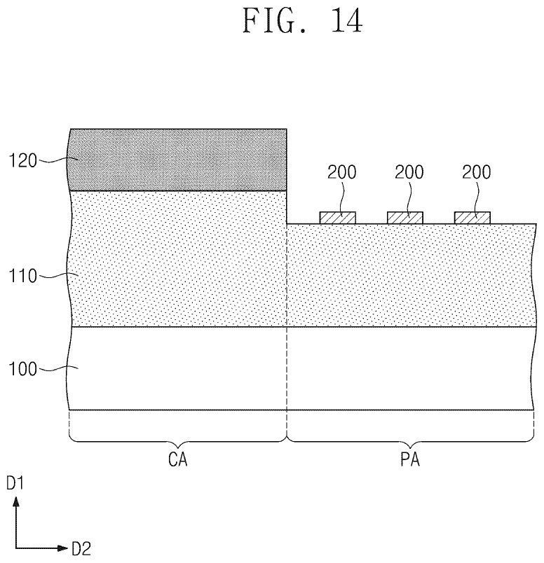

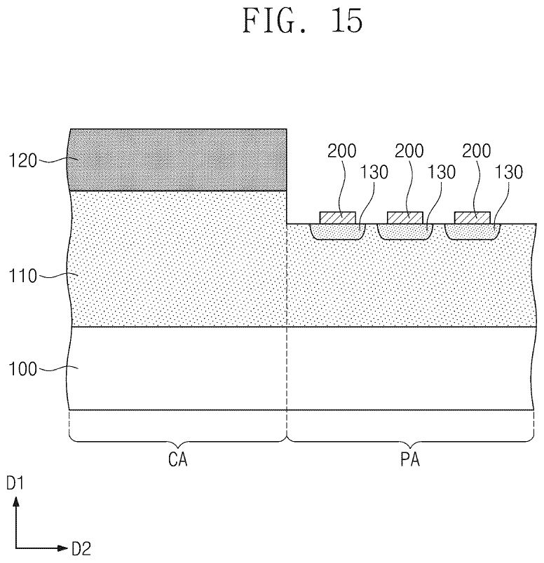

FIG. 11 is a flowchart for schematically describing a method for manufacturing a nitride semiconductor device according to an embodiment of the inventive concept. FIG. 12 is a cross-sectional view for describing a method for manufacturing a nitride semiconductor device according to an embodiment of the inventive concept. FIG. 13 is a cross-sectional view for describing a method for manufacturing a nitride semiconductor device according to another embodiment of the inventive concept. FIGS. 14 and 15 are cross-sectional views for describing a method for manufacturing a nitride semiconductor device according to embodiments of the inventive concept. For brevity, detailed descriptions of components that are identical/similar to those described above may be skipped.

Referring to FIGS. 11 and 12, in a semiconductor device according to an embodiment of the inventive concept, a first nitride layer 110 may be stacked on a nitride substrate 100 in an device region CA and a peripheral region PA (S100).

After the first nitride layer 110 is stacked, a second nitride layer 120 may be stacked on the first nitride layer in the device region CA (S200). For example, the first nitride layer 110 and the second nitride layer 120 may be stacked using processes such as metalorganic chemical vapor deposition (MOCVD), molecular beam epitaxy (MBE), or hydride vapor phase epitaxy (HVPE).

Through the stacking processes (S100, S200) described above, a semiconductor stack (not shown) in which the nitride substrate 100, the first nitride layer 110, and the second nitride layer 120 are stacked may be formed.

After the second nitride layer 120 is stacked, a portion of the first nitride layer 110 and the second nitride layer 120 may be sequentially etched (S300). Through the etching process (S300), the second nitride layer 120 in the peripheral region PA may be etched, and a portion of the first nitride layer 110 in the peripheral region PA may be etched.

Referring to FIGS. 11 and 13, in a nitride semiconductor device according to another embodiment of the inventive concept, a first nitride layer 110 may be stacked on a nitride substrate 100 in an device region CA, a peripheral region PA, and a boundary region BA (S100).

After the first nitride layer 110 is stacked, a second nitride layer 120 may be stacked on the first nitride layer 110 in the device region CA and the boundary region BA (S200).

After the second nitride layer 120 is stacked, a portion of the first nitride layer 110 and the second nitride layer 120 may be sequentially etched (S300) in the boundary region BA and the peripheral region PA. Through the etching process (S300), the second nitride layer 120 in the peripheral region PA may be etched, and a portion of the second nitride layer 120 in the boundary region BA may be etched. Through the etching process (S300), a portion of the first nitride layer 110 may be etched in the peripheral region PA and the boundary region BA. Therefore, a first inclined plane L1 and a second inclined plane L2 may be formed in the boundary region BA. Accordingly, the nitride semiconductor device may have a MESA structure.

Referring to FIGS. 11 and 14, after the etching process (S300) is performed, guard rings 200 may be deposited on the first nitride layer 110 of the peripheral region PA (S400). The guard rings 200 may be deposited in plurality. For example, the guard rings 200 may be stacked using processes such as metalorganic chemical vapor deposition (MOCVD), molecular beam epitaxy (MBE), hydride vapor phase epitaxy (HVPE) or physical vapor deposition (PVD).

Referring to FIGS. 11 and 15, after the guard rings 200 is deposited (S400), an impurity region 130 may be formed in the first nitride layer 110 of the peripheral region PA through a heat treatment process (S500). The heat treatment process may be, for example, a rapid thermal annealing (RTA) process. The heat treatment process may be, for example, performed at a temperature of about 800° C. to about 1000° C. Through the heat treatment process (S500), metal ions in the guard rings 200 may diffuse into the first nitride layer 110, and accordingly, the impurity region 130 adjacent to the guard rings 200 in the first nitride layer 110 may be formed.

When the impurity region 130 is formed, an ion-implantation process may be skipped, and thus, a process of implanting high energy into the first nitride layer 110 may be skipped. Accordingly, surface damage and defects caused by high energy may be mitigated, and leakage current may be reduced.

The heat treatment process for ion activation involved in the ion-implantation process may be skipped. The heat treatment process (S500) (performed at a temperature of about 800° C. to about 1000° C.) may be performed at a temperature lower than the heat treatment process temperature for ion activation (about 1300° C. or greater). Accordingly, surface damage and mobility degradation of the first nitride layer 110, caused by high temperature may be mitigated, and accordingly, the nitride semiconductor device may have enhanced voltage-current performance.

According to embodiments of the inventive concept, a self-edge termination structure may be formed to suppress a peak electric field value of an edge junction between a p-type layer and an n type layer. Accordingly, a nitride semiconductor device may have increased breakdown voltage.

According to embodiments of the inventive concept, when forming a junction termination through a self-edge termination manufacturing process, an ion-implantation process and a heat treatment process for ion activation may be skipped. Accordingly, process costs may be reduced, and defects in vertical nitride semiconductor devices may be mitigated, resulting in enhanced voltage-current performance.

Effects of the present disclosure are not limited to the effects described above, and those skilled in the art may understand other effects from the following description.

Although the embodiments of the inventive concept have been described above with reference to the accompanying drawings, those skilled in the art to which the inventive concept pertains may implement the inventive concept in other specific forms without changing the technical idea or essential features thereof. Therefore, the above-described embodiments are to be considered in all aspects as illustrative and not restrictive.

What is claimed is:

1. A nitride semiconductor device comprising:
a nitride substrate of a first conductive type including an device region and a peripheral region;
a first nitride layer of the first conductive type disposed on the nitride substrate;
a second nitride layer of a second conductive type disposed on the first nitride layer in the device region;
guard rings disposed on the first nitride layer in the peripheral region; and
an impurity region of the second conductive type adjacent to each of the guard rings in the second nitride layer,
wherein an upper surface of the first nitride layer is located at a higher level in the device region than in the peripheral region.

2. The nitride semiconductor device of claim 1, wherein the nitride substrate, the first nitride layer, the second nitride layer, and the impurity region contain GaN.

3. The nitride semiconductor device of claim 1, wherein in a first direction perpendicular to an upper surface of the nitride substrate, a level difference between the upper surface of the first nitride layer in the device region and the upper surface of the first nitride layer in the peripheral region is about 100 nm to about 300 nm.

4. The nitride semiconductor device of claim 3, wherein a thickness of the second nitride layer is greater than the level difference.

5. The nitride semiconductor device of claim 1, wherein a depth in a first direction perpendicular to an upper surface of the nitride substrate in the impurity region is about 10 nm to about 200 nm.

6. The nitride semiconductor device of claim 1, wherein the first nitride layer has an impurity concentration of about 10¹⁵ to about 5*10¹⁶ per cubic centimeter.

7. The nitride semiconductor device of claim 1, wherein the second conductive type is a p-type, and
the guard rings and the impurity region contain magnesium (Mg).

8. The nitride semiconductor device of claim 7, wherein the impurity region has a magnesium (Mg) concentration of about 10¹⁶ to about 10¹⁸ per cubic centimeter.

9. The nitride semiconductor device of claim 1, wherein an upper surface of the guard rings is located at a lower level than the upper surface of the first nitride layer in the device region.

10. A nitride semiconductor device comprising:
a nitride substrate of a first conductive type including an device region, a peripheral region, and a boundary region placed between the device region and the peripheral region;
a first nitride layer of the first conductive type on the nitride substrate, wherein an upper surface of the first nitride layer is located at a higher level in the device region than in the peripheral region;
a second nitride layer of a second conductive type disposed on the first nitride layer of the device region and the boundary region;
guard rings disposed on the first nitride layer of the peripheral region; and
an impurity region of the second conductive type adjacent to each of the guard rings in the first nitride layer of the peripheral region,
wherein the first nitride layer has a first inclined plane in the boundary region,
the second nitride layer has a second inclined plane in the boundary region, and
the first inclined plane and the second inclined plane have an inclination angle of about 5° to less than about 90° with respect to an upper surface of the nitride substrate.

11. The nitride semiconductor device of claim 10, wherein an upper surface of the guard rings is located at a lower level than the upper surface of the first nitride layer in the device region.

12. The nitride semiconductor device of claim 10, wherein in a first direction perpendicular to the upper surface of the nitride substrate, a level difference between the upper surface of the first nitride layer in the device region and the upper surface of the first nitride layer in the peripheral region is about 100 nm to about 300 nm.

13. The nitride semiconductor device of claim 10, wherein a depth in a first direction perpendicular to the upper surface of the nitride substrate in the impurity region is about 10 nm to about 200 nm.

14. A method for manufacturing a nitride semiconductor device, the method comprising:
sequentially stacking a first nitride layer of a first conductive type and a second nitride layer of a second conductive type on a nitride substrate of the first conductive type including an device region and a peripheral region to form a semiconductor stack;
sequentially etching the second nitride layer in the peripheral region and a portion of the first nitride layer in the peripheral region to expose an upper surface of the first nitride layer in the peripheral region;
performing a deposition process to form guard rings on the first nitride layer in the peripheral region; and
performing a heat treatment process to form an impurity region of the second conductive type adjacent to each of the guard rings in the first nitride layer of the peripheral region.

15. The method of claim 14, wherein the heat treatment process is performed at a temperature of about 800° C. to about 1000° C.

16. The method of claim 14, wherein the second conductive type is a p-type, and
the guard rings and the impurity region contain magnesium (Mg).

17. The method of claim 16, wherein the first nitride layer has an impurity concentration of about 10¹⁵/cm³ to about 5*10¹⁶/cm³, and
the impurity region has a magnesium (Mg) concentration of about 10¹⁶/cm³ to about 10¹⁸/cm³.

18. The method of claim 14, wherein an upper surface of the guard rings is located at a lower level than the upper surface of the first nitride layer in the device region.

19. The method of claim 14, wherein in a first direction perpendicular to an upper surface of the nitride substrate, a level difference between the upper surface of the first nitride layer in the device region and the upper surface of the first nitride layer in the peripheral region is about 100 nm to about 300 nm.

20. The method of claim 14, wherein a depth in a first direction perpendicular to an upper surface of the nitride substrate in the impurity region is about 10 nm to about 200 nm.
